(19) United States
(12) Patent Application Publication
(10) Pub. No.: US 2018/0374904 A1
(43) Pub. Date: Dec. 27, 2018

(54) OLED DISPLAY DEVICE AND MANUFACTURING METHOD THEREOF

(71) Applicant: Wuhan China Star Optoelectronics Semiconductor Display Technology Co., Ltd., Wuhan City (CN)

(72) Inventor: Chao Xu, Wuhan City (CN)

(21) Appl. No.: 15/561,985

(22) PCT Filed: Aug. 18, 2017
(86) PCT No.: PCT/CN2017/098141

§ 371 Date: Sep. 27, 2017

(30) Foreign Application Priority Data
Jun. 21, 2017 (CN) 201710477260.1

(51) Int. Cl. H01L 27/32; H01L 51/50; H01L 51/52; H01L 51/56

(52) U.S. Cl. CPC H01L 27/322; H01L 27/3262; H01L 27/3213; H01L 51/56; H01L 51/5044; H01L 51/5237; H01L 51/502

(57) ABSTRACT

The invention provides an OLED display device and manufacturing method thereof. The OLED display device comprises: a TFT substrate, a WOLED layer, a water oxygen barrier layer, a color filter layer, a light extraction layer, and a package cover arranged in turn from the bottom up, wherein the color filter layer comprising a plurality of transparent spacers, red, green, and blue quantum dot units. The invention provides transparent spacers in color filter layer to allow the white light emitted from WOLED layer to pass through to form a white pixel to realize the RGBW four-pixel display, to improve the OLED display luminance; through introducing quantum dots in the color filter layer, the invention improves the color gamut of the OLED display; through adding the water oxygen barrier layer and the light extraction layer above the WOLED layer, the t invention improves the WOLED device life span and light efficiency.

### BACKGROUND OF THE INVENTION

### 1. Field of the Invention

The present invention relates to the field of display techniques, and in particular to an organic light-emitting diode (OLED) display device and manufacturing method thereof.

### 2. The Related Arts

The active matrix panel display provides the advantages of thinness, saving-power, no radiation and many other advantages, and has been widely used. The organic light-emitting diode (OLED) display technology is a highly promising panel display technology, as the OLED has a very excellent display performance, such as, active-luminous, simple structure, ultra-thin, fast response, wide viewing angle, low power consumption and ability to achieve flexible display, and so on, and is known as the “dream display”. Coupled with lower production equipment investment than the thin film transistor liquid crystal display screen (TFT-LCD), the OLED has attracted the major display manufacturers and has become the mains technology in the field of the third generation display device. At present, OLED is on the edge of starting mass production. With the new technology continuing to emerge, OLED display device is heralded to hold a breakthrough development.

To achieve the full color of the OLED display, one approach is through the RGB sub-pixel to emit light in a side-by-side structure, another approach is through a tandem structure of white organic light emitting diode (WOLED) and color filter (CF) stacked together (tandem WOLED+CF). In WOLED, the white light-emitting layer is usually fabricated by mixing the red, blue, and green fluorescent materials and co-evaporation of the mixture. The while light is emitted and RGB colors are obtained through CF layer. Because the WOLED and CF layered stack structure does not require a precise mask process to achieve high resolution OLED display, so WOLED display device is widely recognized as the focus of next generation display technology.

However, in the WOLED and CF tandem structure, the CF layer usually comprises red, green and blue photo-resist units, and the red, green and blue photo-resist units of the CF layer cannot perform good filtering on the white light from the white light-emitting layer. Therefore, the existing tandem structure of the OLED display has some shortcomings, such as, the device efficiency in high brightness and shorter life expectancy, wider half peak width in RGB emission spectrum, narrow color gamut, and so on.

The quantum dot (QD) refers to a semiconductor grain having a particle size of 1-100 nm. Due to the smaller particle size of QD, less than or close to the exciton Bohr radius of the corresponding host material, the quantum confinement effect is generated, and the continuous energy band structure of the host material is transformed into a discrete energy level structure. Under the excitation of the external light source, the electrons will transit and emit the fluorescent. This special discrete level structure of QD makes the half-wave width narrow, which can emit a higher purity monochromatic light, and has a higher luminous efficiency compared to the traditional display. At the same time, due to the QD energy band gap influenced by size, different wavelengths of light can be stimulated by regulating the size of QD or the use of different components of the QD.

### SUMMARY OF THE INVENTION

The object of the present invention is to provide an OLED display device, able to effectively increase the luminance and color gamut of the OLED display device and increase the light-emitting efficiency and life span.

Another object of the present invention is to provide a manufacturing method of OLED display device, able to effectively increase the luminance and color gamut of the OLED display device and increase the light-emitting efficiency and life span.

To achieve the above object, the present invention provides an OLED display device, comprising: a TFT substrate, a WOLED layer disposed on the TFT substrate, a water oxygen barrier layer disposed on the WOLED layer, a color filter layer disposed on the water oxygen barrier layer, a light extraction layer disposed on the color filter layer, and a package cover disposed on the light extraction layer;

wherein the color filter layer comprising a plurality of transparent spacers, a plurality of red quantum dot units, a plurality of green quantum dot units and a plurality of blue quantum dot units; the transparent spacers surrounding to form a plurality of red pixel troughs, a plurality of green pixel troughs, and a plurality of blue pixel troughs on the water oxygen barrier layer; the red quantum dot units, the green quantum dot units and the blue quantum dot units respectively formed corresponding to the red pixel troughs, green pixel troughs and blue pixel troughs.

According to a preferred embodiment of the present invention, the transparent spacer is made of silicon nitride, silicon oxide, titanium oxide or zinc oxide.

According to a preferred embodiment of the present invention, the light extraction layer is made of titanium oxide or zinc oxide.

According to a preferred embodiment of the present invention, the water oxygen barrier layer is made of silicon nitride or silicon oxide.

According to a preferred embodiment of the present invention, the WOLED layer comprises a pixel definition layer and a plurality of WOLED devices separated by the pixel definition layer.

The present invention also provides a manufacturing method of OLED display device, comprising the steps of:

Step S1: providing a TFT substrate, forming a WOLED layer on the TFT substrate, forming a water oxygen barrier layer on the WOLED layer;

Step S2: depositing and patternizing the water oxygen barrier layer to form a plurality of transparent spacers, the transparent spacers surrounding to form a plurality of red pixel troughs, a plurality of green pixel troughs, and a plurality of blue pixel troughs on the water oxygen barrier layer;

Step S3: providing red quantum dot ink, green quantum dot ink, and blue quantum dot ink, coating respectively the red quantum dot ink, green quantum dot ink, and blue quantum dot ink by inkjet printing onto the plurality of red pixel troughs, the plurality of green pixel troughs, and the plurality of blue pixel troughs to form patternized a plurality of red quantum dot units, a plurality of green quantum dot units, and a plurality of blue quantum dot units so as to obtain a color filter layer comprising a plurality of transparent spacers, a plurality of red quantum dot units, a plurality of green quantum dot units, and a plurality of blue quantum dot units;

Step S4: forming a light extraction layer on the color filter layer, covering the light extraction layer with a package cover to accomplish manufacturing the OLED display device.

According to a preferred embodiment of the present invention, in Step S2, the transparent spacer is formed by physical vapor deposition, chemical vapor deposition, atomic layer deposition, or vapor deposition; and the transparent spacer is made of silicon nitride, silicon oxide, titanium oxide or zinc oxide.

According to a preferred embodiment of the present invention, in Step S4, the light extraction layer is formed by spin coating, physical vapor deposition, chemical vapor deposition, atomic layer deposition, or vapor deposition; and the light extraction layer is made of titanium oxide or zinc oxide.

According to a preferred embodiment of the present invention, in Step S1, the water oxygen barrier layer is formed by physical vapor deposition, chemical vapor deposition, atomic layer deposition, or vapor deposition; and the water oxygen barrier layer is made of silicon nitride or silicon oxide.

According to a preferred embodiment of the present invention, the WOLED layer comprises a pixel definition layer and a plurality of WOLED devices separated by the pixel definition layer.

The present invention also provides an OLED display device, comprising: a TFT substrate, a WOLED layer disposed on the TFT substrate, a water oxygen barrier layer disposed on the WOLED layer, a color filter layer disposed on the water oxygen barrier layer, a light extraction layer disposed on the color filter layer, and a package cover disposed on the light extraction layer;

wherein the color filter layer comprising a plurality of transparent spacers, a plurality of red quantum dot units, a plurality of green quantum dot units and a plurality of blue quantum dot units; the transparent spacers surrounding to form a plurality of red pixel troughs, a plurality of green pixel troughs, and a plurality of blue pixel troughs on the water oxygen barrier layer; the red quantum dot units, the green quantum dot units and the blue quantum dot units respectively formed corresponding to the red pixel troughs, green pixel troughs and blue pixel troughs;

wherein the transparent spacer being made of silicon nitride, silicon oxide, titanium oxide or zinc oxide;

wherein the light extraction layer being made of titanium oxide or zinc oxide;

wherein the water oxygen barrier layer being made of silicon nitride or silicon oxide.

Compared to the known techniques, the present invention provides the following advantages. The present invention provides an OLED display device, comprising: a TFT substrate, a WOLED layer, a water oxygen barrier layer, a color filter layer, a light extraction layer, and a package cover arranged in turn from the bottom up, wherein the color filter layer comprising a plurality of transparent spacers, a plurality of red quantum dot units, a plurality of green quantum dot units and a plurality of blue quantum dot units. The present invention provides transparent spacers in the color filter layer to allow the white light emitted from the WOLED layer to pass through to form a white pixel to realize the RGBW four-pixel display, to effectively improve the luminance of the OLED display; moreover, through introducing quantum dots in the color filter layer, the present invention greatly improves the color gamut of the OLED display; through adding the water oxygen barrier layer and the light extraction layer above the WOLED layer, the present invention improves the WOLED device life span and light efficiency. The manufacturing method of OLED display device of the present invention disposes transparent spacers in the color filter layer to allow the white light emitted from the WOLED layer to pass through to form a white pixel to realize the RGBW four-pixel display, to effectively improve the luminance of the OLED display; moreover, through introducing quantum dots in the color filter layer, the present invention greatly improves the color gamut of the OLED display; through adding the water oxygen barrier layer and the light extraction layer above the WOLED layer, the present invention improves the WOLED device life span and light efficiency.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing a flowchart of the manufacturing method of OLED display device provided by an embodiment of the present invention;

FIG. 2 is a schematic view showing Step 1 of the manufacturing method of OLED display device provided by an embodiment of the present invention;

FIG. 3 is a schematic view showing Step 2 of the manufacturing method of OLED display device provided by an embodiment of the present invention;

FIG. 4 is a schematic view showing Step 3 of the manufacturing method of OLED display device provided by an embodiment of the present invention;

FIG. 5 is a schematic view showing Step 4 of the manufacturing method of OLED display device and the structure of the OLED display device provided by an embodiment of the present invention.

### DETAILED DESCRIPTION OF THE PREFERRED EMBODIMENTS

To further explain the technique means and effect of the present invention, the following uses preferred embodiments and drawings for detailed description.

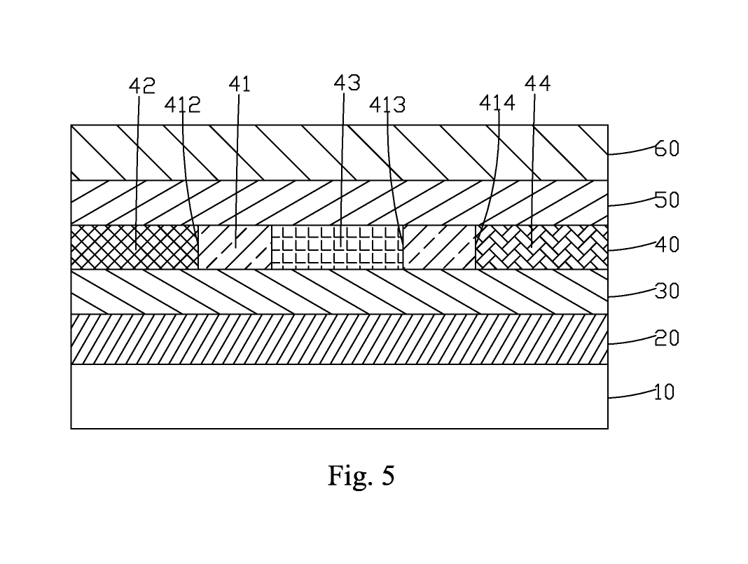

Referring to FIG. 5, the present invention provides an OLED display device, comprising: a TFT substrate 10, a WOLED layer 20 disposed on the TFT substrate 10, a water oxygen barrier layer 30 disposed on the WOLED layer 20, a color filter layer 40 disposed on the water oxygen barrier layer 30, a light extraction layer 50 disposed on the color filter layer 40, and a package cover 60 disposed on the light extraction layer 50;

wherein the color filter layer 40 comprising a plurality of transparent spacers 41, a plurality of red quantum dot units 42, a plurality of green quantum dot units 43 and a plurality of blue quantum dot units 44; the transparent spacers 41 surrounding to form a plurality of red pixel troughs 412, a plurality of green pixel troughs 413, and a plurality of blue pixel troughs 414 on the water oxygen barrier layer 30; the red quantum dot units 42, the green quantum dot units 43 and the blue quantum dot units 44 respectively formed corresponding to the red pixel troughs 412, green pixel troughs 413 and blue pixel troughs 414.

Specifically, the preferred material for the transparent spaces 41 is a material with high light transmittance and good compatibility with the quantum dot ink. Moreover, the transparent spacer 41 is made of silicon nitride (SiNₓ), silicon oxide (SiOₓ), titanium oxide (TiO₂) or zinc oxide (ZnO).

Specifically, the preferred material for the light extraction layer 50 is an inorganic material with better water oxygen blocking property; moreover, the light extraction layer 50 is made of titanium oxide (TiO₂) or zinc oxide (ZnO).

Specifically, the water oxygen barrier layer 30 is for blocking the erosion of the WOLED layer 20 by the water oxygen, and the water oxygen barrier layer 30 is made of silicon nitride or silicon oxide.

Specifically, the WOLED layer 20 comprises a pixel definition layer (not shown) and a plurality of WOLED devices (not shown) separated by the pixel definition layer.

The OLED display device of the present invention, through providing transparent spacers 41 in the color filter layer 40 to allow the white light emitted from the WOLED layer 20 to pass through to form a white pixel to realize the RGBW four-pixel display, to effectively improve the luminance of the OLED display; moreover, through introducing quantum dots in the color filter layer 40, the present invention greatly improves the color gamut of the OLED display; through adding the water oxygen barrier layer 30 and the light extraction layer 50 above the WOLED layer 20, the present invention improves the WOLED device life span and light efficiency.

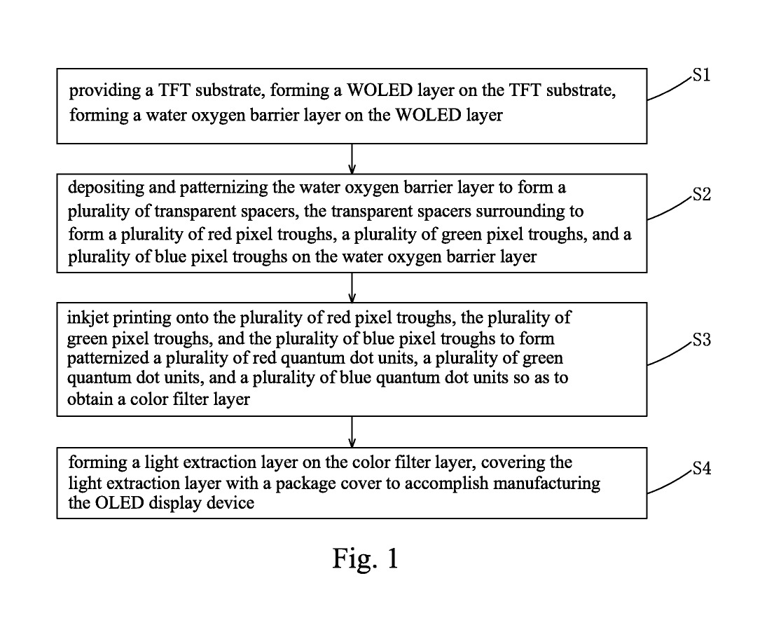

Based on the above OLED display device, referring to FIG. 1, the present invention also provides a manufacturing method of OLED display device, comprising the steps of:

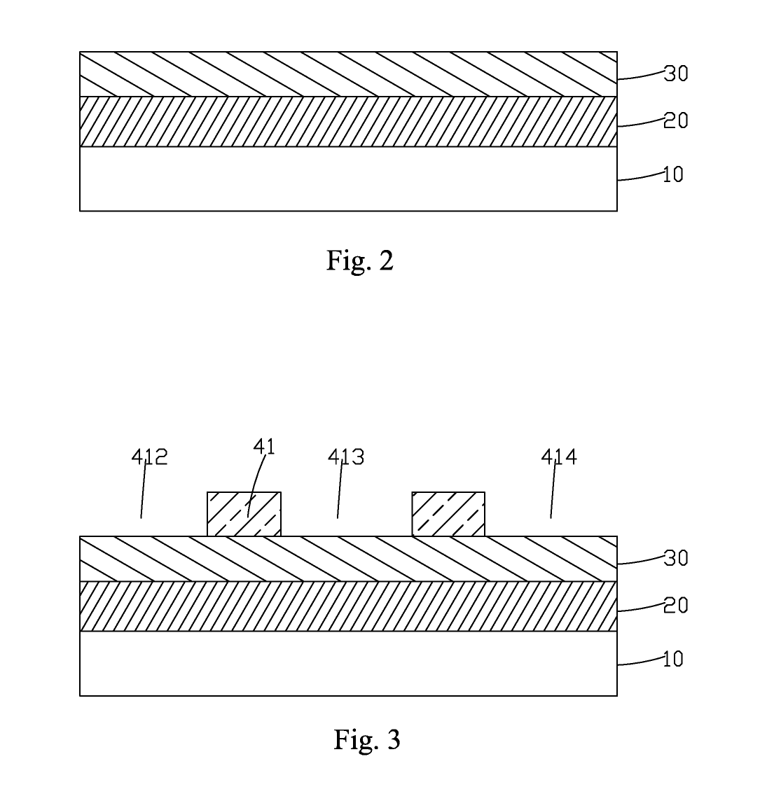

Step S1: as shown in FIG. 2, providing a TFT substrate 10, forming a WOLED layer 20 on the TFT substrate 10, forming a water oxygen barrier layer 30 on the WOLED layer 20.

Specifically, the water oxygen barrier layer 30 is for blocking the erosion of the WOLED layer 20 by the water oxygen, and the water oxygen barrier layer 30 is made of silicon nitride or silicon oxide.

Specifically, in Step S1, the water oxygen barrier layer 30 is formed by physical vapor deposition (PVD), chemical vapor deposition (CVD), atomic layer deposition (ALD), or vapor deposition.

Specifically, the WOLED layer 20 comprises a pixel definition layer and a plurality of WOLED devices separated by the pixel definition layer.

Step S2: as shown in FIG. 3, depositing and patternizing the water oxygen barrier layer 30 to form a plurality of transparent spacers 41, the transparent spacers 41 surrounding to form a plurality of red pixel troughs 412, a plurality of green pixel troughs 413, and a plurality of blue pixel troughs 414 on the water oxygen barrier layer 30.

Specifically, the preferred material for the transparent spaces 41 is a material with high light transmittance and good compatibility with the quantum dot ink. Moreover, the transparent spacer 41 is made of silicon nitride (SiNₓ), silicon oxide (SiOₓ), titanium oxide (TiO₂) or zinc oxide (ZnO).

Specifically, in Step S2, the transparent spacer 41 is formed by physical vapor deposition, chemical vapor deposition, atomic layer deposition, or vapor deposition.

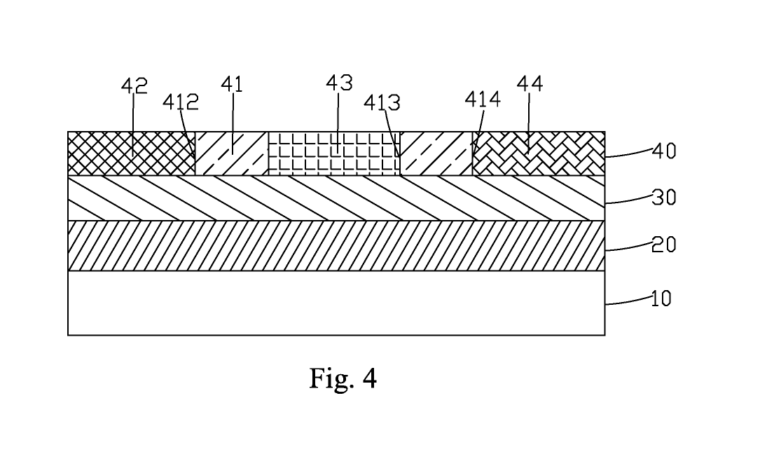

Step S3: as shown in FIG. 4, providing red quantum dot ink, green quantum dot ink, and blue quantum dot ink, coating respectively the red quantum dot ink, green quantum dot ink, and blue quantum dot ink by inkjet printing onto the plurality of red pixel troughs 412, the plurality of green pixel troughs 413, and the plurality of blue pixel troughs 414; then baking and drying to form patternized a plurality of red quantum dot units 42, a plurality of green quantum dot units 43, and a plurality of blue quantum dot units 44 so as to obtain a color filter layer comprising a plurality of transparent spacers 41, a plurality of red quantum dot units 42, a plurality of green quantum dot units 43, and a plurality of blue quantum dot units 44.

Step S4: as shown in FIG. 5, forming a light extraction layer 50 on the color filter layer 40, covering the light extraction layer 50 with a package cover 60, packaging the OLED display device to accomplish manufacturing the OLED display device.

Specifically, the preferred material for the light extraction layer 50 is an inorganic material with better water oxygen blocking property; moreover, the light extraction layer 50 is made of titanium oxide (TiO₂) or zinc oxide (ZnO).

In Step S4, the light extraction layer 50 is formed by spin coating, physical vapor deposition, chemical vapor deposition, atomic layer deposition, or vapor deposition.

In summary, the present invention provides an OLED display device, comprising: a TFT substrate, a WOLED layer, a water oxygen barrier layer, a color filter layer, a light extraction layer, and a package cover arranged in turn from the bottom up, wherein the color filter layer comprising a plurality of transparent spacers, a plurality of red quantum dot units, a plurality of green quantum dot units and a plurality of blue quantum dot units. The present invention provides transparent spacers in the color filter layer to allow the white light emitted from the WOLED layer to pass through to form a white pixel to realize the RGBW four-pixel display, to effectively improve the luminance of the OLED display; moreover, through introducing quantum dots in the color filter layer, the present invention greatly improves the color gamut of the OLED display; through adding the water oxygen barrier layer and the light extraction layer above the WOLED layer, the present invention improves the WOLED device life span and light efficiency. The manufacturing method of OLED display device of the present invention disposes transparent spacers in the color filter layer to allow the white light emitted from the WOLED layer to pass through to form a white pixel to realize the RGBW four-pixel display, to effectively improve the luminance of the OLED display; moreover, through introducing quantum dots in the color filter layer, the present invention greatly improves the color gamut of the OLED display; through adding the water oxygen barrier layer and the light extraction layer above the WOLED layer, the present invention improves the WOLED device life span and light efficiency.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An organic light-emitting diode (OLED) display device, comprising: a thin film transistor (TFT) substrate, a white organic light-emitting diode (WOLED) layer disposed on the TFT substrate, a water oxygen barrier layer disposed on the WOLED layer, a color filter layer disposed on the water oxygen barrier layer, a light extraction layer disposed on the color filter layer, and a package cover disposed on the light extraction layer;
wherein the color filter layer comprising a plurality of transparent spacers, a plurality of red quantum dot units, a plurality of green quantum dot units and a plurality of blue quantum dot units; the transparent spacers surrounding to form a plurality of red pixel troughs, a plurality of green pixel troughs, and a plurality of blue pixel troughs on the water oxygen barrier layer; the red quantum dot units, the green quantum dot units and the blue quantum dot units respectively formed corresponding to the red pixel troughs, green pixel troughs and blue pixel troughs.

2. The OLED display device as claimed in claim 1, wherein the transparent spacer is made of silicon nitride, silicon oxide, titanium oxide or zinc oxide.

3. The OLED display device as claimed in claim 1, wherein the light extraction layer is made of titanium oxide or zinc oxide.

4. The OLED display device as claimed in claim 1, wherein the water oxygen barrier layer is made of silicon nitride or silicon oxide.

5. A manufacturing method of organic light-emitting diode (OLED) display device, comprising the steps of:
Step S1: providing a thin film transistor (TFT) substrate, forming a white organic light-emitting diode (WOLED) layer on the TFT substrate, forming a water oxygen barrier layer on the WOLED layer;
Step S2: depositing and patternizing the water oxygen barrier layer to form a plurality of transparent spacers, the transparent spacers surrounding to form a plurality of red pixel troughs, a plurality of green pixel troughs, and a plurality of blue pixel troughs on the water oxygen barrier layer;
Step S3: providing red quantum dot ink, green quantum dot ink, and blue quantum dot ink, coating respectively the red quantum dot ink, green quantum dot ink, and blue quantum dot ink by inkjet printing onto the plurality of red pixel troughs, the plurality of green pixel troughs, and the plurality of blue pixel troughs to form patternized a plurality of red quantum dot units, a plurality of green quantum dot units, and a plurality of blue quantum dot units so as to obtain a color filter layer comprising a plurality of transparent spacers, a plurality of red quantum dot units, a plurality of green quantum dot units, and a plurality of blue quantum dot units;
Step S4: forming a light extraction layer on the color filter layer, covering the light extraction layer with a package cover to accomplish manufacturing the OLED display device.

6. The manufacturing method of OLED display device as claimed in claim 5, wherein in Step S2, the transparent spacer is formed by physical vapor deposition, chemical vapor deposition, atomic layer deposition, or vapor deposition; and the transparent spacer is made of silicon nitride, silicon oxide, titanium oxide or zinc oxide.

7. The manufacturing method of OLED display device as claimed in claim 5, wherein in Step S4, the light extraction layer is formed by spin coating, physical vapor deposition, chemical vapor deposition, atomic layer deposition, or vapor deposition; and the light extraction layer is made of titanium oxide or zinc oxide.

8. The manufacturing method of OLED display device as claimed in claim 5, wherein in Step S1, the water oxygen barrier layer is formed by physical vapor deposition, chemical vapor deposition, atomic layer deposition, or vapor deposition; and the water oxygen barrier layer is made of silicon nitride or silicon oxide.

9. An organic light-emitting diode (OLED) display device, comprising: a thin film transistor (TFT) substrate, a white organic light-emitting diode (WOLED) layer disposed on the TFT substrate, a water oxygen barrier layer disposed on the WOLED layer, a color filter layer disposed on the water oxygen barrier layer, a light extraction layer disposed on the color filter layer, and a package cover disposed on the light extraction layer;
wherein the color filter layer comprising a plurality of transparent spacers, a plurality of red quantum dot units, a plurality of green quantum dot units and a plurality of blue quantum dot units; the transparent spacers surrounding to form a plurality of red pixel troughs, a plurality of green pixel troughs, and a plurality of blue pixel troughs on the water oxygen barrier layer; the red quantum dot units, the green quantum dot units and the blue quantum dot units respectively formed corresponding to the red pixel troughs, green pixel troughs and blue pixel troughs;
wherein the transparent spacer being made of silicon nitride, silicon oxide, titanium oxide or zinc oxide;
wherein the light extraction layer being made of titanium oxide or zinc oxide;
wherein the water oxygen barrier layer being made of silicon nitride or silicon oxide.
